(19) United States
(12) Patent Application Publication
(10) Pub. No.: US 2011/0287365 A1
(43) Pub. Date: Nov. 24, 2011

(54) LITHOGRAPHIC PRINTING PLATE PRECURSORS

(76) Inventors: Oliver Piestert, Schwetzingen (DE); Harald Baumann, Osterode (DE); Stefan Kull, Osterode (DE)

(21) Appl. No.: 12/782,951

(22) Filed: May 19, 2010

(51) Int. Cl. G03F 7/20; G03F 7/004

(52) U.S. Cl. 430/284.1; 430/270.1; 430/302

(57) ABSTRACT

A backside coating is applied to lithographic printing plate precursors and this coating provides sufficient protection so that adjacent precursors are not scratched or otherwise damaged when stacked. The backside coating is readily dissolved during processing or development at a pH of at least 6.5 after the precursors are imaged.

### FIELD OF THE INVENTION

This invention relates to lithographic printing plate precursors having unique non-radiation-sensitive coatings on the non-imaging backside of the substrate. This invention also relates to stacks of the lithographic printing plate precursors that are provided for shipping, storage, and use without interleaf papers between adjacent precursors. Further, this invention also relates to a method of providing imaged and processed lithographic printing plates whereby the unique coatings are dissolved.

### BACKGROUND OF THE INVENTION

Radiation-sensitive compositions are routinely used in the preparation of imageable materials including lithographic printing plate precursors. Such compositions generally include a radiation-sensitive component and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Usually lithographic printing plate precursors are supplied to customers in a stack of multiple precursors, usually at least 20 precursors, with interleaf (or slip sheet) papers between adjacent precursors to prevent adhesion to one another and scratches on the imageable side. Without such interleaf papers, damage to the imageable front side from an adjacent precursor back side may occur during factory finishing operations, transportation, storage, or during use in plate setter devices.

There has been a desire to eliminate the use of interleaf paper to reduce waste and to simplify the loading process into imaging devices. One approach for doing this is described in EP 1,865,380 (Endo) in which silica-coated polymer particles are added to the topcoat. Organic filler particles are used in a similar manner in the materials of EP 1,839,853 (Yanaka et al.).

It is known that back side coatings can be used to prevent scratching if interleaf papers are omitted. However, this requires finding the best compromise between a smooth backside surface for preventing scratching of imaging surface in an adjacent precursor front side during transportation, and the need for the back side surface to be established securely on a printing press. If the back side surface is too smooth, the printing plate is more likely to move in the printing press clamps during printing, causing cracking in the printing surface.

In addition, copending and commonly assigned U.S. Ser. No. 12/336,635 (filed Dec. 17, 2008 by Ray, Mulligan, and Beckley) describes the use of a topcoat that has a dry coating weight of 1 g/m² or less. This technique also avoids the use of polymer coatings on the backside of the aluminum-containing substrate.

Further, various coatings or matting agents have been used on the back side of lithographic printing plate precursors to eliminate the need for interleaf papers in stacks of the precursors. Some of these treatments are described for example in EP Publications 1,747,883 (Watanabe), 1,767,379 (Kawauchi), 1,790,492 (Nagashima), 1,829,703 (Kawauchi), 1,834,802 (Watanabe), 1,921,501 (Yamamoto et al.), and 1,923,228 (Xiangfeng), and U.S. Patent Application Publication 2006/0216638 (Watanabe).

Despite these various attempts to avoid interleaf papers, there remains a need for better ways to avoid the use of interleaf papers while protecting the imaging surfaces of lithographic printing plates so they do not move during printing and become cracked in the printing surface.

### SUMMARY OF THE INVENTION

The present invention provides a lithographic printing plate precursor comprising a substrate and having thereon a radiation-sensitive imageable layer on the front side the substrate,

the precursor being developable in a processing solution having a pH of at least 6.5 after imagewise irradiation using imaging radiation,

the precursor further comprising a non-radiation-sensitive layer on the back side of the substrate, whereby at least 80 weight % of the non-radiation-sensitive layer is removable when contacted by the processing solution for 5 to 50 seconds at 20° C. to 40° C.

This invention also provides a stack comprising two or more of the lithographic printing plate precursors of this invention, wherein the non-radiation-sensitive layer of an uppermost precursor is in direct contact with the front side of the precursor below it, without interleaf paper between the adjacent precursors.

Further, this invention includes a method of providing a lithographic printing plate comprising:
A) imagewise exposing the lithographic printing plate precursor of this invention to provide imagewise exposed and non-exposed regions in the radiation-sensitive imageable layer on the front side,
B) prior to or after step A, contacting the lithographic printing plate precursor using a processing solution having a pH of at least 6.5, for 5 to 50 seconds at 20° C. to 40° C., to remove at least 80 weight % of the non-radiation-sensitive layer on the back side of the substrate, and
C) after step A, but prior to, during, or after step B, processing the precursor to provide a lithographic image on its front side.

The lithographic printing plate precursors of this invention comprise a radiation-sensitive imageable layer that is sensitive to radiation in the range of 350 to 450 nm or in the range of from 750 to 1250 nm.

The present invention provides a way to avoid the use of interleaf papers between adjacent lithographic printing plate precursors. Such lithographic printing plate precursors can be positive-working or negative-working and can comprise any of a variety of imageable layer chemistries. The improvement and advantages are provided with a particular back side (non-imaging side) coating that can be removed before, during, or after imaging using a variety of processing solutions and in various processing apparatus. Thus, it is not critical as to the type of imaging chemistry that is used on the front side of the precursors as long as the back side is properly designed according to this invention.

The back side coating provides a sufficiently smooth surface for the precursors to be safely stacked during manufacture and transportation. Yet, there are no problems when the printing plate is secured on a printing press because the backside layer has been removed during development, leaving a slightly rougher back side surface of the precursor substrate.

More particularly, the non-radiation-sensitive layer on the back side of the substrate (that is usually an aluminum-containing substrate) is partially or totally removed using a processing solution having a pH of at least 6.5. Such processing solutions (as described in more detail below) can be rinse solutions used before or after development, or developers, rinse solutions, or gumming solutions that used either during or after development. Thus, there is considerable flexibility in how the back side layer is removed depending upon the particular lithographic printing plate precursors and imaging processes that are used.

The back side layer is designed with specific components to enable the back side to be at least partially removal at the appropriate time. In some instances, the back side layer is only partially removed and the residue on the substrate is adhered to the substrate to provide desired roughness features. In other instances, a matte agent or other particulates can be dispersed within a continuous matrix or binder composition on the back side and after partial removal of the back side layer, the remaining matte agent or particulates provide desired roughness.

Further details of the invention and the advantages they provide can be understood from the following teaching.

### DETAILED DESCRIPTION OF THE INVENTION

### Definitions

Unless the context indicates otherwise, when used herein, the terms “lithographic printing plate precursor”, “printing plate precursor”, and “precursor” are meant to be references to embodiments of the present invention.

In addition, unless the context indicates otherwise, the various components described for use in the lithographic printing plate precursors and developing or processing solutions (“developers”) also refer to mixtures of such components. Thus, the use of the articles “a”, “an”, and “the” is not necessarily meant to refer to only a single component.

Moreover, unless otherwise indicated, percentages refer to percents by dry weight, for example, weight % based on total solids or dry layer composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

As used herein, a “stack” of lithographic printing plate precursors includes two or more of the precursors in which there is no interleaf paper between adjacent precursors. Generally, a stack has at least two and more typically from 20 to 1500 lithographic printing plate precursors, or at least 100 of them, or at least 250 and up to 800 of the lithographic printing plate precursors, and no interleaf papers are present between any adjacent lithographic printing plate precursors in the stack.

### Substrates

The substrate used to prepare the lithographic printing plate precursors of this invention comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that can be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of from about 1.5 to about 5 g/m² and more typically from about 2.5 to about 4 g/m². Phosphoric acid anodization generally provides an oxide weight on the surface of from about 1 to about 5 g/m² and more typically from about 1.5 to about 3 g/m². When sulfuric acid is used for anodization, higher oxide weight (at least 3 g/m²) can provide longer press life.

The aluminum support can also be treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support can be treated with a phosphate solution that can further contain an inorganic fluoride (PF).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Back Side Non-Radiation-Sensitive Layer

The back side (non-imaging side) of the substrate has a non-radiation-sensitive layer (also known herein as the back coat). At least 80 weight % of the non-radiation-sensitive layer is removable when contacted by a processing solution (described below) for 5 to 50 seconds at 20° C. to 40° C. In some embodiments, at least 80 weight % of the non-radiation-sensitive layer is removable in the processing solution that is an alkaline developer comprising a silicate or metasilicate and having a pH of at least 8 and up to 14 (such as 8 to 13), when the precursor is contacted with the processing solution for 10 to 30 seconds at 20° C. to 30° C.

In still other embodiments, at least 80 weight % of the non-radiation-sensitive layer is removable in the processing solution that is free of silicates and metasilicates and has a pH of from 6.5 to 12.5, when the precursor is contacted with the processing solution for 10 to 30 seconds at 20° C. to 30° C.

Upon removal of the non-radiation-sensitive layer, the back side surface of the substrate (usually an aluminum substrate) has a roughness Rₐ of at least 0.1 μm, or typically at least 0.15 μm or from 0.15 μm to 0.4 μm. The roughness Rₐ factor is the “arithmetic mean roughness” and is measured according to the standard ISO 25178 (stylus method) in both the web and traverse directions. For example, this substrate can comprise an anodized and grained aluminum support. In addition, aluminum sheet substrates can be roughened electrochemically or mechanically (for example, by embossing) before the non-radiation-sensitive layer is applied. Thus, the desired Rₐ value can be achieved using electrochemical or mechanical roughening of the substrate or the presence of matte agent (described below), or a combination of both.

In general, the non-radiation-sensitive layer is composed of a non-crosslinked polymeric material in an amount of at least 80 weight % based on the total layer dry weight, or more likely at least 90 weight %, and up to 100 weight % of the total layer dry weight.

For example, the non-radiation-sensitive layer comprises one or more of the following materials in an amount of at least 80 weight % based on the total layer dry weight:

a poly(vinyl alcohol,

poly(vinyl pyrrolidone) or a copolymer derived in part from vinyl pyrrolidone,

a starch,

gum Arabic,

a polymer having pendant acidic groups, or salts thereof,

a poly(alkylene oxide),

a novolak or resole resin,

a poly(vinyl acetal) with acidic or phenolic groups,

a polyurethane with acidic side groups, and

hydrophilic wax dispersion.

Such materials are readily available from a number of commercial sources, or they can be readily prepared (for example, the synthetic polymers) using known starting materials and reaction conditions.

In some embodiments, the non-radiation-sensitive layer comprises one or more non-removable components that are not removable in the processing solution under the noted processing conditions. These non-removable components can comprise less than 20 weight % of the total layer dry weight, and generally they comprise less than 10 weight % of the total layer dry weight.

For example, the non-radiation-sensitive layer can comprise discontinuous particulate materials dispersed as a discontinuous phase within one or more binder materials that act as a continuous matrix or phase. Useful discontinuous particulate materials include but are not limited to, polymeric matte agents, inorganic particles such as silica particles, aluminum oxide particles, and titanium dioxide particles, or mixtures of both organic and inorganic particulate materials. The inorganic particles can be modified on their surface to prevent agglomeration during coating and in the processing solution. These discontinuous particulate materials are inert in the sense that they do not react or otherwise interfere with the performance of the processing solution or use of the lithographic printing plate precursor. However, they may remain on the back side of the substrate when the non-radiation-sensitive layer is partially removed to provide desired roughness of the back side surface.

The non-radiation-sensitive layer is generally present at a dry coverage of 0.1 to 5 g/m², and in some embodiments it is present at a dry coverage of from about 0.3 to about 2 g/m².

In addition, the non-radiation-sensitive layer can further includes one or more of a plasticizer, surfactant, matte agent, dye, or pigment.

The back side layers can be provided on the substrate using a variety of conventional techniques, including slot coating, dip coating, roller coating, ink jet spraying, and electrostatic spraying under known conditions. The back coat formulation is formed by dissolving or dispersing the desired components, including desired polymers, matte agent, and other addenda in suitable solvents such as water, alcohols (such as methanol, ethanol, and propanol), ketones (such as methyl ether ketone), esters (such as ethyl acetate and butyl acetate), glycol derivatives (such as ethylene glycol monomethyl ether, ethylene glycol monoethyl ether, propylene glycol monomethyl ether, and propylene glycol monomethyl ether acetate) and mixtures of these solvents.

### Positive-Working Lithographic Printing Plate Precursors

Some of the lithographic printing plate precursors of the present invention are positive-working and include one or more layers disposed on a suitable substrate that has a hydrophilic surface or at least a surface that is more hydrophilic than the applied imageable layer on the imaging side.

Some embodiments of such positive-working lithographic printing plate precursors comprise a single imageable surface layer while others comprise an inner layer and an outer surface layer disposed on the inner layer.

The lithographic printing plate precursors can rely on an infrared radiation absorbing compound dispersed within one or more polymeric binders that, upon suitable irradiation, are soluble, dispersible, or removable in processing solutions including alkaline developers. Thus, the imageable layer(s), upon irradiation, undergoes a change in solubility properties with respect to the processing solution in its irradiated (exposed) regions.

For example, “single-layer” positive-working lithographic printing plate precursors are described for example, in EP 1,543,046 (Timpe et al.), WO 2004/081662 (Memetea et al.), U.S. Pat. No. 6,255,033 (Levanon et al.), U.S. Pat. No. 6,280,899 (Hoare et al.), U.S. Pat. No. 6,391,524 (Yates et al.), U.S. Pat. No. 6,485,890 (Hoare et al.), U.S. Pat. No. 6,558,869 (Hearson et al.), U.S. Pat. No. 6,706,466 (Parsons et al.), U.S. Pat. No. 6,541,181 (Levanon et al.), U.S. Pat. No. 7,223,506 (Kitson et al.), U.S. Pat. No. 7,247,418 (Saraiya et al.), U.S. Pat. No. 7,270,930 (Hauck et al.), U.S. Pat. No. 7,279,263 (Goodin), and U.S. Pat. No. 7,399,576 (Levanon), EP 1,627,732 (Hatanaka et al.), and U.S. Published Patent Applications 2005/0214677 (Nagashima), 2004/0013965 (Memetea et al.), 2005/0003296 (Memetea et al.), and 2005/0214678 (Nagashima).

The surface layer can contain one or more phenolic polymeric binders that are generally soluble in alkaline developers (defined below) after thermal imaging. In most embodiments of the lithographic printing plate precursors, these polymeric binders are present in an amount of at least 10 weight % and typically from about 20 to about 80 weight % of the total dry imageable layer weight. By “phenolic”, we mean a hydroxyl-substituted phenyl group.

Useful phenolic polymers include but are not limited to, poly(vinyl phenols) or derivatives thereof. They can also include pendant acidic groups such as carboxylic(carboxy), sulfonic(sulfo), phosphonic(phosphono), or phosphoric acid groups that are incorporated into the polymer molecule or pendant to the polymer backbone. Other useful additional phenolic polymers include but are not limited to, novolak resins, resole resins, poly(vinyl acetals) having pendant phenolic groups, and mixtures of any of these resins (such as mixtures of one or more novolak resins and one or more resole resins). Generally, such resins have a number average molecular weight of at least 3,000 and up to 200,000, and typically from about 6,000 to about 100,000, as determined using conventional procedures. Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or a m,p-cresol mixture with formaldehyde using conventional conditions. For example, some useful novolak resins include but are not limited to, xylenol-cresol resins, for example, SPN400, SPN420, SPN460, and VPN1100 (that are available from AZ Electronics) and EP25D4OG and EP25D5OG (noted below for the Examples) that have higher molecular weights, such as at least 4,000.

Other useful additional resins include polyvinyl compounds having phenolic hydroxyl groups, include poly(hydroxystyrenes) and copolymers containing recurring units of a hydroxystyrene and polymers and copolymers containing recurring units of substituted hydroxystyrenes. Also useful are branched poly(hydroxystyrenes) having multiple branched hydroxystyrene recurring units derived from 4-hydroxystyrene as described for example in U.S. Pat. No. 5,554,719 (Sounik) and U.S. Pat. No. 6,551,738 (Ohsawa et al.), and U.S. Published Patent Applications 2003/0050191 (Bhatt et al.), 2005/0051053 (Wisnudel et al.), and 2008/2008/0008956 (Levanon et al.). For example, such branched hydroxystyrene polymers comprise recurring units derived from a hydroxystyrene, such as from 4-hydroxystyrene, which recurring units are further substituted with repeating hydroxystyrene units (such as 4-hydroxystyrene units) positioned ortho to the hydroxy group. These branched polymers can have a weight average molecular weight (M_{w}) of from about 1,000 to about 30,000. In addition, they can have a polydispersity less than 2. The branched poly(hydroxystyrenes) can be homopolymers or copolymers with non-branched hydroxystyrene recurring units.

Another group of useful polymeric binders are poly(vinyl phenol) and derivatives thereof. Such polymers are obtained generally by polymerization of vinyl phenol monomers, that is, substituted or unsubstituted vinyl phenols. Some vinyl phenol copolymers are described in EP 1,669,803A (Barclay et al.).

The positive-working lithographic printing plate precursor also includes one or more radiation absorbing compounds in the surface imageable layer. Such compounds are sensitive to near-infrared or infrared radiation, for example of from about 700 to about 1400 nm and typically from about 700 to about 1200 nm.

Useful IR-sensitive radiation absorbing compounds include carbon blacks and other IR-absorbing pigments and various IR-sensitive dyes (“IR dyes”). Examples of suitable IR dyes include but are not limited to, azo dyes, squarilium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), and U.S. Pat. No. 6,787,281 (Tao et al.), and EP 1,182,033A2 (noted above). A general description of one class of suitable cyanine dyes is shown by the formula in paragraph [0026] of WO 2004/101280 (Munnelly et al.).

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanabe et al.). Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Some useful IR cyanine dyes include a borate anion, such as a tetra-substituted borate anion, which substituents can be the same or different alkyl (having 1 to 20 carbon atoms) or aryl groups (phenyl or naphthyl groups), which groups can be further substituted if desired. Particularly useful boron-containing counterions of this type include alkyltriarylborates, dialkyldiarylborates, and tetraarylborates. Examples of these boron-containing counterions are described for example, in EP 438,123A2 (Murofushi et al.).

Useful radiation absorbing compounds can be obtained from a number of commercial sources or they can be prepared using known starting materials and procedures.

The radiation absorbing compound (or sensitizer) can be present in the imageable layer in an amount generally of at least 0.5% and up to and including 30% and typically at least 3 and up to and including 20%, based on total solids. The particular amount needed for this purpose would be readily apparent to one skilled in the art, depending upon the specific compound used to provide the desired chromophore.

In some embodiments, the IR radiation absorbing compound is present in the single surface imageable layer. Alternatively or additionally, the IR radiation absorbing compounds can be located in a separate layer that is in thermal contact with the single surface imageable layer. Thus, during imaging, the action of the IR radiation absorbing compound can be transferred to the single surface imageable layer without the compound originally being incorporated into it.

The single-layer surface imageable element can be prepared by applying the layer formulation to the substrate (including any hydrophilic layers on an aluminum sheet or cylinder) using conventional coating or lamination methods. Thus, the formulations can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support (such as an on-press printing cylinder or printing sleeve).

The coating weight for the single surface imageable layer can be from about 0.5 to about 2.5 g/m² and typically from about 1 to about 2 g/m².

The selection of solvents used to coat the surface imageable layer formulation depends upon the nature of the polymeric materials and other components in the formulations. Generally, the formulation is coated out of acetone, methyl ethyl ketone, or another ketone, tetrahydrofuran, 1-methoxypropan-2-ol, 1-methoxy-2-propyl acetate, and mixtures thereof using conditions and techniques well known in the art. The coated layer can be dried in a suitable manner.

Other positive-working lithographic printing plate precursors of this invention are multi-layer imageable elements comprise a substrate, an inner layer (also known in the art as an “underlayer”), and an outer surface layer (also known in the art as a “top layer” or “topcoat”) disposed over the inner layer.

Before thermal imaging, the outer layer is generally not soluble or removable by an alkaline developer within the usual time allotted for development, but after thermal imaging, the exposed regions of the outer surface layer are soluble in the alkaline developer. The inner layer is also generally removable by the alkaline developer. An infrared radiation absorbing compound (described above) can also be present in such imageable elements, and is typically present in the inner layer but can optionally be in a separate layer between the inner and outer layers. Useful IR radiation absorbing compounds are described above.

Thermally imageable, multi-layer lithographic printing plate precursors are described, for example, in U.S. Pat. No. 6,294,311 (Shimazu et al.), U.S. Pat. No. 6,352,812 (Shimazu et al.), U.S. Pat. No. 6,593,055 (Shimazu et al.), U.S. Pat. No. 6,352,811 (Patel et al.), U.S. Pat. No. 6,358,669 (Savariar-Hauck et al.), U.S. Pat. No. 6,528,228 (Savariar-Hauck et al.), U.S. Pat. No. 7,163,770 (Saraiya et al.), U.S. Pat. No. 7,163,777 (Ray et al.), 7,186,482 (Kitson et al.), U.S. Pat. No. 7,223,506 (noted above), U.S. Pat. No. 7,229,744 (Patel), U.S. Pat. No. 7,241,556 (Saraiya et al.), U.S. Pat. No. 7,247,418 (noted above), U.S. Pat. No. 7,291,440 (Ray et al.), U.S. Pat. No. 7,300,726 (Patel et al.), and U.S. Pat. No. 7,338,745 (Ray et al.), U.S. Patent Application Publications 2004/0067432 A1 (Kitson et al.) and 2005/0037280 (Loccufier et al.).

These multi-layer lithographic printing plate precursors are formed by suitable application of an inner layer composition onto a suitable substrate. This substrate can be an untreated or uncoated support but it is usually treated or coated in various ways as described above prior to application of the inner layer composition. The substrate generally has a hydrophilic surface or at least a surface that is more hydrophilic than the outer layer composition. The substrate comprises a support that can be composed of any material that is conventionally used to prepare lithographic printing plates. Further details of such substrates are provided above in relation to the single-layer precursors.

The inner layer is disposed between the outer surface layer and the substrate. Typically, it is disposed directly on the substrate (including any hydrophilic coatings as described above). The inner layer comprises a first polymeric binder that is removable by the lower pH processing solution of this invention and typically soluble in that processing solution to reduce sludging. In addition, the first polymeric binder is usually insoluble in the solvent used to coat the outer surface layer so that the outer surface layer can be coated over the inner layer without dissolving the inner layer. Mixtures of these first polymeric binders can be used if desired in the inner layer. Such polymeric binders are generally present in the inner layer in an amount of at least 10 weight %, and generally from about 60 to 95 weight % of the total dry inner layer weight.

In most embodiments, the inner layer further comprises an infrared radiation absorbing compound (as described above) that absorbs radiation at from about 700 to about 1400 and typically at from about 700 to about 1200 nm. In most embodiments, the infrared radiation absorbing compound is present only in the inner layer. The infrared radiation absorbing compound can be present in the multi-layer lithographic printing plate precursor in an amount of generally at least 0.5% and up to 30% and typically from about 3 to about 25%, based on the total dry weight of the layer in which the compound is located. The particular amount of a given compound to be used could be readily determined by one skilled in the art.

The outer surface layer of the imageable element is disposed over the inner layer and in most embodiments there are no intermediate layers between the inner and outer surface layers. The outer surface layer generally comprises a second polymeric binder that is usually different than the first polymeric binder described above for the inner layer. This second polymeric binder is a phenolic polymeric binder as described above for the single-layer lithographic printing plate precursor. In many embodiments, the outer surface layer is substantially free of infrared radiation absorbing compounds, meaning that none of these compounds are purposely incorporated therein and insubstantial amounts diffuse into it from other layers. However, in other embodiments, the infrared radiation absorbing compound can be in both the outer surface and inner layers, as described for example in EP 1,439,058A2 (Watanabe et al.) and EP 1,738,901A1 (Lingier et al.), or in an intermediate layer as described above.

The outer surface layer can also include colorants as described for example in U.S. Pat. No. 6,294,311 (noted above) including triarylmethane dyes such as ethyl violet, crystal violet, malachite green, brilliant green, Victoria blue B, Victoria blue R, and Victoria pure blue BO. These compounds can act as contrast dyes that distinguish the non-exposed regions from the exposed regions in the developed imageable element. The outer surface layer can optionally also include contrast dyes, printout dyes, coating surfactants, dispersing aids, humectants, biocides, viscosity builders, drying agents, defoamers, preservatives, and antioxidants.

The multi-layer lithographic printing plate precursors can be prepared by sequentially applying an inner layer formulation over the surface of the hydrophilic substrate, and then applying an outer layer formulation over the inner layer using conventional coating or lamination methods. It is important to avoid intermixing of the inner and outer surface layer formulations.

The inner and outer surface layers can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support.

The selection of solvents used to coat both the inner and outer surface layers depends upon the nature of the first and second polymeric binders, other polymeric materials, and other components in the formulations.

To prevent the inner and outer surface layer formulations from mixing or the inner layer from dissolving when the outer surface layer formulation is applied, the outer surface layer formulation should be coated from a solvent in which the first polymeric binder(s) of the inner layer are insoluble. Generally, the inner layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane.

The outer surface layer formulation can be coated out of solvents or solvent mixtures that do not dissolve the inner layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof. Particularly useful is a mixture of DEK and PMA, or a mixture of DEK, PMA, and isopropyl alcohol.

After drying the layers, the lithographic printing plate precursors can be further “conditioned” with a heat treatment at from about 40 to about 90° C. for at least 4 hours (for example, at least 20 hours) under conditions that inhibit the removal of moisture from the dried layers. For example, the heat treatment is carried out at from about 50 to about 70° C. for at least 24 hours. During the heat treatment, the lithographic printing plate precursors are wrapped or encased in a water-impermeable sheet material to represent an effective barrier to moisture removal from the precursors, or the heat treatment of the precursors is carried out in an environment in which relative humidity is controlled to at least 25%. In addition, the water-impermeable sheet material can be sealed around the edges of the precursors, with the water-impermeable sheet material being a polymeric film or metal foil that is sealed around the edges of the precursors.

In some embodiments, this heat treatment can be carried out with a stack comprising at least 100 of the same lithographic printing plate precursors, or when the precursor is in the form of a coil or web. When conditioned in a stack, the individual precursors can be separated by suitable interleaving papers. The interleaving papers can be kept between the imageable elements after conditioning during packing, shipping, and use by the customer.

### Negative-Working Polymerization Lithographic Printing Plate Precursors

In other embodiments of this invention, the precursors are negative-working, and can be formed by suitable application of a radiation-sensitive composition as described above to a suitable substrate (described above) to form an imageable layer. This substrate can be treated or coated in various ways as described above prior to application of the radiation-sensitive composition to improve hydrophilicity. There can be only a single imageable layer comprising the radiation-sensitive composition and it is the outermost layer in the element. In other embodiments, the element includes what is conventionally known as an overcoat (or an oxygen barrier or oxygen impermeable topcoat) applied to and disposed over the imageable layer.

Negative-working imageable elements are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 6,899,994 (Huang et al.), U.S. Pat. No. 7,045,271 (Tao et al.), U.S. Pat. No. 7,049,046 (Tao et al.), U.S. Pat. No. 7,261,998 (Hayashi et al.), U.S. Pat. No. 7,279,255 (Tao et al.), U.S. Pat. No. 7,285,372 (Baumann et al.), U.S. Pat. No. 7,291,438 (Sakurai et al.), U.S. Pat. No. 7,326,521 (Tao et al.), U.S. Pat. No. 7,332,253 (Tao et al.), U.S. Pat. No. 7,442,486 (Baumann et al.), U.S. Pat. No. 7,452,638 (Yu et al.), U.S. Pat. No. 7,524,614 (Tao et al.), U.S. Pat. No. 7,560,221 (Timpe et al.), U.S. Pat. No. 7,574,959 (Baumann et al.), U.S. Pat. No. 7,615,323 (Shrehmel et al.), and U.S. Pat. No. 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.). Other negative-working compositions and elements are described for example in Japanese Kokai 2000-187322 (Takasaki), 2001-330946 (Saito et al.), 2002-040631 (Sakurai et al.), 2002-341536 (Miyamoto et al.), and 2006-317716 (Hayashi).

The radiation-sensitive compositions and imageable layers used in such precursors generally include one or more polymeric binders. Some polymeric binders are designed for off-press developability and include alkaline solution soluble (or dispersible) polymers having an acid value of from about 20 to about 400 (typically from about 30 to about 200). The following described polymeric binders are useful in this manner but this is not an exhaustive list:

I. Polymers formed by polymerization of a combination or mixture of (a) (meth)acrylonitrile, (b) poly(alkylene oxide)esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference.

II. Polymers having pendant allyl ester groups as described in U.S. Pat. No. 7,332,253 (Tao et al.) that is incorporated herein by reference. Such polymers may also include pendant cyano groups or have recurring units derived from a variety of other monomers.

III. Polymers having all carbon backbones wherein at least 40 and up to 100 mol % (and typically from about 40 to about 50 mol %) of the carbon atoms forming the all carbon backbones are tertiary carbon atoms, and the remaining carbon atoms in the all carbon backbone being non-tertiary carbon atoms. Such polymers are described for example in U.S. Patent Application Publication 2008-0280229 (Tao et al.).

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. In some embodiments, the reactive vinyl group is attached to the polymer backbone through a phenylene group as described, for example, in U.S. Patent 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. No. 4,874,686 (Urabe et al.), U.S. Pat. No. 7,729,255 (Tao et al.), U.S. Pat. No. 6,916,595 (Fujimaki et al.), and U.S. Pat. No. 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Application Publication 2009/0142695 (Baumann et al.).

VI. Still other useful polymeric binders may be homogenous, that is, dissolved in the coating solvent, or may exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. No. 6,309,792 (Hauck et al.), U.S. Pat. No. 6,352,812 (Shimazu et al.), U.S. Pat. No. 6,569,603 (noted above), and U.S. Pat. No. 6,893,797 (Munnelly et al.). Also useful are the vinyl carbazole polymers described in U.S. Pat. No. 7,175,949 (Tao et al.).

Other useful polymeric binders are particulate poly (urethane-acrylic) hybrids that are distributed (usually uniformly) throughout the imageable layer. Some poly (urethane-acrylic) hybrids are commercially available in dispersions from Air Products and Chemicals, Inc. (Allentown, Pa.), for example, as the Hybridur® 540, 560, 570, 580, 870, 878, and 880 polymer dispersions of poly (urethane-acrylic) hybrid particles.

Other polymeric binders are used to promote on-press developability, and include but are not limited to, those that are not generally crosslinkable and are usually present as discrete particles (not-agglomerated). Such polymers can be present as discrete particles having an average particle size of from about 10 to about 500 nm, and typically from 100 to 450 nm, and that are generally distributed uniformly within that layer. The particulate polymeric binders exist at room temperature as discrete particles, for example in an aqueous dispersion. Such polymeric binders generally have a molecular weight (Mₙ) of at least 5,000 and typically at least 20,000 and up to 100,000, or from 30,000 to 80,000, as determined by Gel Permeation Chromatography.

Useful particulate polymeric binders generally include polymeric emulsions or dispersions of polymers having hydrophobic backbones to which are attached pendant poly(alkylene oxide) side chains, cyano side chains, or both, that are described for example in U.S. Pat. No. 6,582,882 (Pappas et al.), U.S. Pat. No. 6,899,994 (Huang et al.), U.S. Pat. No. 7,005,234 (Hoshi et al.), and U.S. Pat. No. 7,368,215 (Munnelly et al.) and US Patent Application Publication 2005/0003285 (Hayashi et al.). More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, and various hydrophilic polymeric binders that may have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, N.Y., 1989, pp. 102-177, by B. M. Monroe in Radiation Curing: Science and Technology, S. P. Pappas, Ed., Plenum, N.Y., 1992, pp. 399-440, and in “Polymer Imaging” by A. B. Cohen and P. Walker, in Imaging Processes and Material, J. M. Sturge et al. (Eds.), Van Nostrand Reinhold, N.Y., 1989, pp. 226-262. For example, useful free radically polymerizable components are also described in EP 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). Other useful free radically polymerizable components include those described in U.S. Patent Application Publication 2009/0142695 (noted above) that include 1H-tetrazole groups.

In addition to, or in place of the free radically polymerizable components described above, the radiation-sensitive composition may include polymeric materials that include side chains attached to the backbone, which side chains include one or more free radically polymerizable groups (such as ethylenically unsaturated groups) that can be polymerized (crosslinked) in response to free radicals produced by the initiator composition (described below). There may be at least two of these side chains per molecule. The free radically polymerizable groups (or ethylenically unsaturated groups) can be part of aliphatic or aromatic acrylate side chains attached to the polymeric backbone. Generally, there are at least 2 and up to 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators that are capable of generating free radicals sufficient to initiate polymerization of all the various free radically polymerizable components upon exposure of the composition to imaging radiation.

The radiation-sensitive composition includes an initiator composition that is capable of generating radicals sufficient to initiate polymerization of the radically polymerizable component upon exposure to the appropriate imaging radiation. The initiator composition may be responsive, for example, to electromagnetic radiation in the infrared spectral regions, corresponding to the broad spectral range of from about 700 nm to about 1400 nm, and typically from 700 nm to 1250 nm. Alternatively, the initiator composition may be responsive to exposing radiation in the ultraviolet or violet region of from about 150 to about 475 nm and typically from 250 to 450 nm. U.S. Pat. No. In general, suitable initiator compositions for IR-radiation and violet-radiation sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). For “violet”-sensitive compositions, initiators include but not limited to, hexaarylbiimidazoles, oxime esters, or trihalomethyl substituted triazines.

Useful initiator compositions for IR radiation sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.).

Useful IR radiation-sensitive initiator compositions can comprise one or more diaryliodonium borate compounds. Representative iodonium borate compounds useful in this invention include but are not limited to, 4-octyloxyphenyl phenyliodonium tetraphenylborate, [44(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexylphenyliodonium tetrakis(penta-fluorophenyl)borate, 4-methylphenyl-4′-dodecylphenyliodonium tetrakis(4-fluorophenyl)borate, bis(dodecylphenyl)iodonium tetrakis(pentafluorophenyl)borate, and bis(4-t-butylphenyl)iodonium tetrakis(1-imidazolyl)borate. Useful compounds include bis(4-t-butylphenyl)iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 300 nm and up to and including 450 nm. Useful sensitizers for such compositions include certain pyrilium and thiopyrilium dyes and 3-ketocoumarins. Some other useful sensitizers for such spectral sensitivity are described for example, in U.S. Pat. No. 6,908,726 (Korionoff et al.) and WO 2004/074929 (Baumann et al.) that describe useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

The imageable layers can comprise a radiation-sensitive imaging composition that includes one or more infrared radiation absorbing compounds, examples of which are described above.

Useful IR-radiation sensitive compositions are described, for example, in the following patent, publications, and copending patent applications:

U.S. Pat. No. 7,452,638 (Yu et al.),

U.S. Patent Application Publication 2008/0254387 (Yu et al.),

U.S. Patent Application Publication 2008/0299488 (Yu et al.),

U.S. Patent Application Publication 2008/0311520 (Yu et al.),

U.S. Ser. No. 12/104,544 (filed Apr. 17, 2008 by Ray et al.), and

U.S. Ser. No. 12/177,208 (filed Jul. 22, 2008 by Yu et al.).

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an outermost imageable layer.

Illustrative of such manufacturing methods is mixing the various components needed for a specific imaging chemistry including oxygen scavenger, polymeric binder, initiator composition, radiation absorbing compound, and any other components of the radiation-sensitive composition in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer.

The lithographic printing plate precursor can also include a water-soluble or water-dispersible overcoat (also sometimes known as an “oxygen impermeable topcoat” or “oxygen barrier layer”) disposed over the imageable or radiation-sensitive layer. Such overcoat layers can comprise one or more water-soluble poly(vinyl alcohol)s having a saponification degree of at least 90% and generally have a dry coating weight of at least 0.1 and up to and including 2 g/m² (typically from about 0.4 to about 2.5 g/m²) in which the water-soluble poly(vinyl alcohol)s comprise at least 60% and up to 99% of the dry weight of the overcoat layer.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.).

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (noted above).

Lithographic Printing Plate Precursors with Coalesceable Imageable Layers

Some lithographic printing plate precursors of this invention have a single thermally-sensitive imageable layer consisting essentially of an infrared radiation absorbing compound and core-shell particles that coalesce upon thermal imaging. This imageable layer is disposed on a suitable substrate that has a back side layer as described above. The core of the core-shell particles is composed of a hydrophobic thermoplastic polymer and the shell of the core-shell particles is composed of a hydrophilic polymer that is covalently bonded to the core hydrophobic thermoplastic polymer.

Other lithographic printing plate precursors having coalesceable imageable layers are described in many publications including but not limited to, U.S. Pat. No. 6,218,073 (Shimizu et al.), U.S. Pat. No. 6,509,133 (Watanabe et al.), U.S. Pat. No. 6,627,380 (Saito et al.), U.S. Pat. No. 6,692,890 (Huang et al.), U.S. Pat. No. 6,030,750 (Vermeersch et al.), U.S. Pat. No. 6,110,644 (Vermeersch et al.), U.S. Pat. No. 5,609,980 (Matthews et al.), and EP 514,145A1 (Matthews et al.) and EP 1,642,714A1 (Wilkinson et al.). Still other precursors and methods of providing an image are described in copending and commonly assigned U.S. Patent Application Publication 2009/0183647 (Jarek) that is incorporated herein by reference.

### Imaging Conditions

During use, the lithographic printing plate is exposed to a suitable source of exposing radiation depending upon the radiation absorbing compound present in the radiation-sensitive composition to provide specific sensitivity that is at a wavelength of from about 150 to about 475 nm or from about 700 to about 1400 nm. In some embodiments, imagewise exposure is carried out using radiation the range of from 350 to 450 nm, or in the range of from 750 to 1250 nm.

For example, imaging can be carried out using imaging or exposing radiation from an infrared laser (or array of lasers) at a wavelength of at least 750 nm and up to and including about 1400 nm and typically at least 750 nm and up to and including 1200 nm. Imaging can be carried out using imaging radiation at multiple wavelengths at the same time if desired.

The laser used to expose the lithographic printing plate precursor is usually a diode laser, because of the reliability and low maintenance of diode laser systems, but other lasers such as gas or solid-state lasers may also be used.

The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 150 nm and up to and including 475 nm), can be carried out generally using energies of at least 0.01 mJ/cm² and up to and including 0.5 mJ/cm², and typically at least 0.02 and up to and including about 0.1 mJ/cm². It would be desirable, for example, to image the UV/visible radiation-sensitive imageable elements at a power density in the range of at least 0.5 and up to and including 50 kW/cm² and typically of at least 5 and up to and including 30 kW/cm², depending upon the source of energy (violet laser or excimer sources)

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

### Development and Printing

After imaging, the imaged precursors can be processed “off-press” using a suitable processing solution described herein. Such processing is carried out for a time sufficient to remove predominantly only the non-exposed regions of the imaged imageable layer to reveal the hydrophilic surface of the substrate, but not long enough to remove significant amounts of the exposed regions. The revealed hydrophilic surface repels inks while the exposed regions accept ink. Thus, the non-exposed regions to be removed are “soluble” or “removable” in the processing solution because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged element with a sponge or cotton pad sufficiently impregnated with a suitable developer (described below), and followed by rinsing with water. “Dip” development involves dipping the imaged element in a tank or tray containing the appropriate developer for about 10 to about 60 seconds (especially from about 20 to about 40 seconds) under agitation, followed by rinsing with water with or without rubbing with a sponge or cotton pad. The use of automatic development apparatus is well known and generally includes pumping a developer or processing solution into a developing tank or ejecting it from spray nozzles. The imaged precursor is contacted with the developer in an appropriate manner. The apparatus may also include a suitable rubbing mechanism (for example a brush or roller) and a suitable number of conveyance rollers. Some developing apparatus include laser exposure means and the apparatus is divided into an imaging section and a developing section.

In the method of this invention, step B is used to remove at least 80 weight % of the non-radiation-sensitive layer on the back side of the substrate, using a processing solution as described below. In general, this step is carried out using a processing solution having a pH of at least 6.5 and up to 14 for 5 to 50 seconds (typically 10 to 30 seconds) at 20° C. to 40° C. (typically 20° C. to 30° C.).

In some embodiments, the processing solution is an alkaline developer (described below) containing one or more silicates or metasilicates) and having a pH of at least 8 and up to 14, or typically up to 13.

In other embodiments, the processing solution is free of silicates and metasilicates (that is, none purposely added) and has a pH of from 6.5 to 12.5 (typically from 7 to 12). Such processing solutions can include simply water, rinse solutions, or fountain solutions.

In some embodiments, step B is carried simultaneously with step C, off-press such as in an automatic processing machine, and the processing solution is an alkaline developer containing a silicate or a metasilicate. Thus, steps B and C are combined as the developer is used to both provide the lithographic image on the front side of the imagewise exposed lithographic printing plate precursor, and to remove the non-radiation-sensitive layer on the back side of the substrate.

In other embodiments, step B is carried out after step A (imagewise exposure) but before step C (processing to form a lithographic image, for example development) and the processing solution is an aqueous rinse solution that is free of silicates and metasilicates. Rinse solutions and their use or application according to this invention would be readily known to one skilled in the art.

Still again, in other embodiments, step B is carried out after steps A and C and the processing solution is an aqueous post-rinse solution that is free of silicates and metasilicates. Such post-rinse solutions are well known in the art. It would be readily apparent how such post-rinse solutions could be applied according to this invention.

In many embodiments of this invention, step B removes at least 80 weight % of the non-radiation-sensitive layer and the substrate is an aluminum-containing substrate having a back side roughness Rₐ of at least 0.1 μm where the non-radiation-sensitive layer is removed. In other embodiments, step B removes at least 80 weight %, but less than 95 weight %, of the non-radiation-sensitive layer, leaving non-removable components that are adhered to the back side of the substrate that is an anodized and grained aluminum substrate after steps B and C.

The resulting lithographic image is used for lithographic printing.

Both aqueous alkaline developers and organic solvent-containing developers can be used. Some useful developer solutions are described for example, in U.S. Pat. No. 7,507,526 (Miller et al.) and U.S. Pat. No. 7,316,894 (Miller et al.). Developer solutions commonly include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates).

Useful alkaline aqueous developer solutions include 3000 Developer, 9000 Developer, GOLDSTAR Developer, GREENSTAR Developer, ThermalPro Developer, PROTHERM Developer, MX1813 Developer, and MX1710 Developer (all available from Eastman Kodak Company). These compositions also generally include surfactants, chelating agents (such as salts of ethylenediaminetetraacetic acid), and alkaline components (such as inorganic metasilicates, organic metasilicates, hydroxides, and bicarbonates).

Organic solvent-containing developers are generally single-phase processing solutions of one or more organic solvents that are miscible with water. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of from about 0.5 and up to 15% based on total developer weight. The organic solvent-containing developers can be neutral, alkaline, or slightly acidic in pH, and typically, they are alkaline in pH.

Representative organic solvent-containing developers include ND-1 Developer, Developer 980, Developer 1080, 2 in 1 Developer, 955 Developer, D29 Developer (described below), and 956 Developer (all available from Eastman Kodak Company). These developers can be diluted with water if desired.

The processing solution (or developer) can be applied to the imaged element by rubbing, spraying, jetting, dipping, immersing, slot die coating (for example see FIGS. 1 and 2 of U.S. Pat. No. 6,478,483 of Maruyama et al.) or reverse roll coating (as described in FIG. 4 of U.S. Pat. No. 5,887,214 of Kurui et al.), or by wiping the outer layer with the processing solution or contacting it with a roller, impregnated pad, or applicator. For example, the imaged element can be brushed with the processing solution, or it can be poured onto or applied by spraying the imaged surface with sufficient force to remove the non-exposed regions using a spray nozzle system as described for example in [0124] of EP 1,788,431A2 (noted above) and U.S. Pat. No. 6,992,688 (Shimazu et al.). As noted above, the imaged element can be immersed in the processing solution and rubbed by hand or with an apparatus. To assist in the removal of the back side coating, a brush roller or other mechanical component can be placed in contact with the back side coating during processing. Alternatively, the processing solution can be sprayed using a spray bar using a force that will help the removal of the back side coating.

The processing solution can also be applied in a processing unit (or station) in a suitable apparatus that has at least one roller for rubbing or brushing the imaged element while the processing solution is applied. By using such a processing unit, the non-exposed regions of the imaged layer may be removed from the substrate more completely and quickly. Residual processing solution may be removed (for example, using a squeegee or nip rollers) or left on the resulting printing plate without any rinsing step. Excess processing solution can be collected in a tank and used several times, and replenished if necessary from a reservoir. The processing solution replenisher can be of the same concentration as that used in processing, or be provided in concentrated form and diluted with water at an appropriate time.

Following off-press development, the resulting lithographic printing plate can be postbaked with or without blanket or floodwise exposure to UV or visible radiation. Alternatively, a blanket UV or visible radiation exposure can be carried out, without a postbake operation. As noted above, Step B can also be carried out at Step C (development).

Printing can be carried out by putting the imaged and developed lithographic printing plate on a suitable printing press. The lithographic printing plate is generally secured in the printing plate using suitable clamps or other holding devices. Once the lithographic printing plate is secured in the printing press, printing is carried out by applying a lithographic printing ink and fountain solution to the printing surface of the lithographic printing plate. The fountain solution is taken up by the surface of the hydrophilic substrate revealed by the imaging and processing steps, and the ink is taken up by the remaining regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material (for example, sheets of paper). The imaged members can be cleaned between impressions, if desired, using conventional cleaning means.

The present invention provides at least the following embodiments and combinations thereof:

1. A lithographic printing plate precursor comprising a substrate and having thereon a radiation-sensitive imageable layer on the front side the substrate,

the precursor being developable in a processing solution having a pH of at least 6.5 after imagewise irradiation using imaging radiation,

the precursor further comprising a non-radiation-sensitive layer on the back side of the substrate, whereby at least 80 weight % of the non-radiation-sensitive layer is removable when contacted by the processing solution for 5 to 50 seconds at 20° C. to 40° C.

2. The lithographic printing plate precursor of embodiment 1 wherein at least 80 weight % of the non-radiation-sensitive layer is removable in the processing solution that is an alkaline developer comprising a silicate or metasilicate and having a pH of at least 8, when the precursor is contacted by the processing solution for 10 to 30 seconds at 20° C. to 30° C.

3. The lithographic printing plate precursor of embodiment 1 wherein at least 80 weight % of the non-radiation-sensitive layer is removable in the processing solution that is free of silicates and metasilicates and has a pH of from 6.5 to 12.5, when the precursor is contacted by the processing solution for 10 to 30 seconds at 20° C. to 30° C.

4. The lithographic printing plate precursor of any of embodiments 1 to 3 wherein, upon removal of the non-radiation-sensitive layer, the backside surface of the substrate has a roughness Rₐ of at least 0.1 μm.

5. The lithographic printing plate precursor of any of embodiments 1 to 4 wherein the substrate comprises an anodized and grained aluminum support.

6. The lithographic printing plate precursor of any of embodiments 1 to 5 wherein the non-radiation-sensitive layer is composed of a non-crosslinked polymeric material in an amount of at least 80 weight % based on the total layer dry weight.

7. The lithographic printing plate precursor of any of embodiments 1 to 6 wherein the non-radiation-sensitive layer comprises one or more of the following materials in an amount of at least 80 weight % based on the total layer dry weight:

a poly(vinyl alcohol,

poly(vinyl pyrrolidone) or a copolymer derived in part from vinyl pyrrolidone,

a starch,

gum Arabic,

a polymer having pendant acidic groups, or salts thereof,

a poly(alkylene oxide),

a novolak or resole resin,

a poly(vinyl acetal) with acidic or phenolic groups,

a polyurethane with acidic side groups, and

hydrophilic wax dispersion.

8. The lithographic printing plate precursor of any of embodiments 1 to 7 wherein the non-radiation-sensitive layer comprises one or more non-removable components that are not removable in the processing solution under the noted conditions, and these non-removable components comprise less than 20 weight % of the total layer dry weight.

9. The lithographic printing plate precursor of any of embodiments 1 to 8 wherein the non-radiation-sensitive layer comprises discontinuous particulate materials dispersed within one or more binder materials.

10. The lithographic printing plate precursor of any of embodiments 1 to 9 wherein the non-radiation-sensitive layer is present at a dry coverage of 0.1 to 5 g/m².

11. The lithographic printing plate precursor of any of embodiments 1 to 10 wherein the non-radiation-sensitive layer is present at a dry coverage of from about 0.3 to about 2 g/m².

12. The lithographic printing plate precursor of any of embodiments 1 to 11 wherein the non-radiation-sensitive layer further includes one or more of a plasticizer, surfactant, matte agent, dye, or pigment.

13. The lithographic printing plate precursor of any of embodiments 1 to 12 wherein the radiation-sensitive imageable layer is sensitive to radiation in the range of 350 to 450 nm or in the range of from 750 to 1250 nm.

14. The lithographic printing plate precursor of any of embodiments 1 to 13 wherein the radiation-sensitive imageable layer is sensitive to infrared radiation and is positive-working

15. The lithographic printing plate precursor of any of embodiments 1 to 14 wherein the radiation-sensitive imageable layer is sensitive to infrared radiation and positive-working, and is disposed over an inner layer that is disposed on the substrate.

16. The lithographic printing plate precursor of any of embodiments 1 to 13 wherein the radiation-sensitive imageable layer is negative-working

17. The lithographic printing plate precursor of any of embodiments 1 to 13 wherein the radiation-sensitive imageable layer comprises particles that are coalesceable upon exposure to imaging radiation.

18. A stack comprising two or more of the lithographic printing plate precursors of any of embodiments 1 to 17, wherein the non-radiation-sensitive layer of an uppermost precursor is in direct contact with the front side of the precursor below it, without interleaf paper between the adjacent precursors.

19. The stack of embodiment 18 comprising at least 20 of the lithographic printing plate precursors, wherein no interleaf paper is provided between any adjacent precursors.

20. A method of providing a lithographic printing plate comprising:
A) imagewise exposing the lithographic printing plate precursor of any of embodiments 1 to 17 to provide imagewise exposed and non-exposed regions in the radiation-sensitive imageable layer on the front side,
B) prior to or after step A, contacting the lithographic printing plate precursor with a processing solution having a pH of at least 6.5, for 5 to 50 seconds at 20° C. to 40° C., to remove at least 80 weight % of the non-radiation-sensitive layer on the back side of the substrate, and
C) after step A, but prior to, during, or after step B, processing the precursor to provide a lithographic image on its front side.

21. The method of embodiment 20 wherein the imagewise exposing is carried out using radiation the range of from 350 to 450 nm, or in the range of from 750 to 1250 nm.

22. The method of embodiment 20 or 21 wherein step B is carried simultaneously with step C, off-press, and the processing solution is an alkaline developer containing a silicate or a metasilicate.

23. The method of embodiment 20 or 21 wherein step B is carried out after step A but before step C and the processing solution is an aqueous rinse solution that is free of silicates and metasilicates.

24. The method of embodiment 20 or 21 wherein step B is carried out after steps A and C and the processing solution is an aqueous post-rinse solution that is free of silicates and metasilicates.

25. The method of any of embodiments 20 to 24 wherein step B removes at least 80 weight %, but less than 95 weight %, of the non-radiation-sensitive layer, leaving non-removable components that are adhered to the back side of the substrate that is an anodized and grained aluminum substrate after steps B and C.

26. The method of any of embodiments 20 to 25 wherein the lithographic image is used for lithographic printing.

### EXAMPLES

The following examples are provided to illustrate the practice of this invention and are not meant to be limiting in any manner.

The following components were used in the examples:

| | |
|---|---|
| Byk ® 307 | Polyether modified polydimethylsiloxane from BYK |
| | (Germany) |
| Crystal Violet | Basic Violet (C.I. 42555) |
| Desmodur ® | Trifunctional isocyanate (biuret of hexamethylene diisocyanate), |
| N100 | available from Bayer/Germany, |
| Dye 1 | Basonyl Violet 610 available from BASF/Germany |
| Epoxy resin 1 | ER1009, manufactured by JAPAN EPOXY RESIN CO., LTD |
| Ethylan ™ | Ethoxylate C₁₀ to C₁₂ alcohol from |
| SN 90 | Akzo Nobel |
| HEMA | (2-Hydroxyethyl)methacrylate |
| HEPi | 2-(2-Hydroxyethyl)-piperidine |
| THPE | 1,1,1-Tris(4-hydroxyphenyl)ethane |
| HMDI | Hexamethylene diisocyanate |
| IR Dye 1 | 2-[2-[2-Thiophenyl-3-[2-(1,3-dihydro-1,3,3-trimethyl-2H-indole- |
| | 2-ylidene)-ethylidene]-1-cyclohexene-1-yl]-ethenyl]-1,3,3- |
| | trimethyl-3H-indoliumchloride |
| IR Dye 2 | 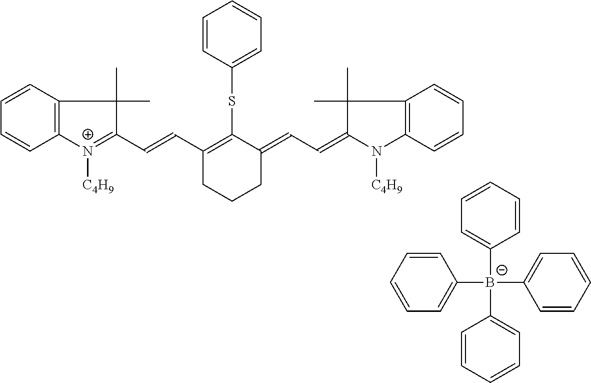 |
| IR Dye 3 | 2-[2-[2-Chloro-3-[2-(1,3-dihydro-1,3,3-trimethyl-2H-benzeindol-2- |
| | ylidene)ethylidene]-1-cyclohexen-1-yl]ethenyl]-1,3,3-trimethyl-1H- |
| | benzindolium 4-methylbenzenesulfonate |
| Kayamer | Ester of 1 mol phosphoric acid and |
| PM-2 | 1.5 mol hydroxyethyl methacrylate, available from Nippon |
| | Kayaku/Japan |
| Monomer 1 | reaction product of 1 mol 2-(2-hydroxyethyl) piperidine with 2 |
| | mol hydroxyethyl methacrylate and 2 mol hexamethylene diisocyanate |
| | (30% solution in ethyl acetate) |
| Monomer 2 | Urethane acrylate (80% solution in methyl ethyl ketone, prepared by |
| | reacting Desmodur ® N100 with hydroxyethyl acrylate and |
| | pentaerythritol triacrylate: 0.5 double bonds per 100 g, when all |
| | isocyanate groups have reacted) |
| Monomer 3 | 30 Weight % in methyl ethyl ketone of an oligomer made by |
| | reaction of 1 mol Desmodur ® N100 (trifunctional isocyanate |
| | (biuret of hexamethylene diisocyanate), available from |
| | Bayer/Germany) + 2 mol glycerol dimethacrylate + 1 mol |
| | polyethylene glycol methacrylate |
| NK Ester | Ethoxylated Bisphenol A having |
| BPE-500 | methacrylic end groups available from Shin Nakamura/Japan |
| Pigment 1 | Pigment dispersion in propylene glycol monomethyl ether |
| | containing 9 wt. % of copper phthalocyanine and 1 wt. % of a |
| | poly(vinyl acetal) binder containing 39.9 mol % vinyl alcohol, 1.2 mol |
| | % vinyl acetate, 15.4 mol % acetal groups from acetaldehyde, 36.1 |
| | mol % acetal groups from butyraldehyde and 7.4 acetal |
| | groups from 4-formylbenzoic acid |
| Pluriol ® P 400 | Polypropylenoxide 430 g/mol from BASF (Germany) |
| Polymer 1 | Copolymer derived from benzyl methacrylate, N-isopropyl |
| | methacrylamide, allyl methacrylate, and methacrylic acid (weight % |
| | ratio of 27:20:39:13) |
| Polymer 2 | Terpolymer made of 47% styrene, 34% methyl methacrylate and 19 |
| | methacrylic acid |
| Polymer 3 | Joncryl ® 683 acrylic resin available from SC Johnson & Son Inc. USA, |
| | acid number = 162 mg KOH/g |
| Polymer 4 | Copolymer of benzyl |
| | methacrylate/allyl methacrylate/methacrylic acid |
| | molar ration of 20/60/20 |
| Polymer 5 | Corresponds to Polymer A disclosed in the examples of |
| | U.S. Pat. No. 7,399,576 |
| S 0094 | IR dye (absorption maximum at 813 nm) available from FEW |
| | (Germany) |
| Sensi 1 | 2-Phenyl-4-(2-chlorophenyl)-5-(4-diethylaminophenyl)-oxazole |
| Tego ® Glide 440 | Polyether siloxane copolymer available from Tego (Germany) |

### Lithographic Printing Plate Precursor Substrate:

A 0.30 mm gage aluminum substrate was electrochemically roughened and anodized to get an oxide weight of 3 g/m² and was subjected to an after treatment using an aqueous solution of polyvinyl phosphoric acid. The average roughness of the surface was 0.55 μm.

### Coating Compositions:

Coating compositions having the components shown in TABLES 1 to 5 were applied to the front side of a substrate after filtering with a wire bar coater.

The coating compositions of TABLES 1 to 3 were overcoated with an aqueous solution of poly(vinyl alcohol) (Celvol® 203 from Air Products, having a hydrolysis degree of 88%) with a wire bar coater to provide a lithographic printing plate precursor having a dry coating weight after drying for 4 minutes at 90° C. The coating weight of the poly(vinyl alcohol) top layer was 2.1 g/m².

For demonstrating the necessity of the backside coating, the scratch sensitivity of the resulting printing plate precursors was determined. Afterwards, the printing plate precursors were imagewise exposed and developed using a developer described below. During development, the backside coating was removed. The resulting lithographic printing plates were used for printing (Invention Examples). For demonstrating the importance of an uncoated backside for printing, the backside of some developed plates was coated again with the backside coating (Comparative Examples) and used for printing.

### Exposure and Development of 405 nm (“UV”)-Sensitive Plates:

The printing plate precursors of Invention Examples 1 to 6 in TABLE 6 and Comparative Examples 4, 7, and 12 were exposed using an platesetter (Prosetter from Heidelberger Druckmaschinen) that was equipped with a laser diode emitting at 405 nm (P=30 mW). An UGRA gray scale V2.4 with defined tonal values was exposed onto the printing plate precursors. The precursors were heated directly after exposure for 2 minutes at 90° C. The precursors were then developed using Developer D1. The sensitivity of the printing plate precursors was determined using an UGRA Offset test scale 1982 with overall flood exposure using the platesetter disclosed above. The exposure energy for such printing plate precursors is defined as the energy needed in order to obtain two grey scale steps of an UGRA scale of the developed printing plate. The results are shown below in TABLE 6.

### Exposure and Development of 830 nm Sensitive Plates:

The UGRA/FOGRA Postscript Strip version 2.0 EPS (available from UGRA), which contains different elements for evaluating the quality of the copies, was used for imaging the printing plate precursors of Invention Examples 7-31 and Comparative Examples 2, 3, 5, 6, 8-11, and 13-16 in TABLE 6 using a Kodak® Trendsetter 3244 (830 nm). The printing plate precursors prepared using the composition of TABLE 2, were heated directly after exposure for 2 minutes to 90° C. The printing plate precursors prepared using the composition of TABLE 5, were heated for 2 minutes before development for by using an oven at a temperature of 127° C. The imaged printing plate precursors were then developed in one bath in using the developers described in TABLE 6 using a processor having 2 brushes from both front and back sides followed by a rinse section, gumming section, and drying section.

### Scratch Sensitivity:

The scratch sensitivity was measured by producing a stack of 20 lithographic printing plate precursors (each having a size of 210 mm by 297 mm) without interleaf paper between adjacent precursors. The stack was tightly wrapped in aluminized black wrapping paper and sealed with adhesive tape. The package was fixed with double-sided adhesive tape on a GFL 3019 shaker for 20 minutes using a shaking frequency of 100 per minute. Afterwards, the number of scratches on the 10^{th} printing plate precursor in the stack was determined after fully exposing the precursor using the same energy as described for imagewise exposure at 405 nm and 830 nm, followed by development. The results are shown below in TABLE 6

### Number of Plates Cracked on Press:

Twice, 20 lithographic printing plate precursors were put on a web press and used to print 200,000 copies. The number of cracked plates was counted during printing, and the results are shown in TABLE 6.

The results from the Invention Examples and Comparative Examples described herein show that the lithographic printing plate precursors having a backside coating according to this invention, which coating was removed during processing had low scratch sensitivity when precursors were stacked without using interleaf paper. Furthermore, it is apparent that the number of printing plates that cracked on press during printing was lower for the printing plates having no backside coating remaining after processing according to the present invention.

TABLE 1
Photosensitive composition for a negative working
photopolymer layer sensitized to 405 nm with coating weight of 1.6 g/m²

| 40 | g | Propylene glycol monomethyl ether |
|---|---|---|
| 5 | g | Acetone |
| 1.39 | g | Polymer 1 |
| 2 | g | Pigment 1 |
| 0.04 | g | Kayamer PM-2 |
| 5.63 | g | Monomer 1 |
| 0.33 | g | NK Ester BPE-500 |
| 0.62 | | Sensi 1 |
| 0.15 | g | 2,2-Bis-(-2-chlorophenyl)-4,5,4′,5′- |
| | | tetraphenyl-2′H-[1,2′]biimidazolyl |
| 0.28 | g | 1H-1,2,4-triazole-5-thiol |

TABLE 2
Photosensitive composition for a negative working photopolymer
layer sensitized to 830 nm with coating weight of 1.4 g/m²

| | |
|---|---|
| 36 g | Propylene glycol monomethyl ether |
| 4 g | Methyl ethyl ketone |
| 4.72 g | Polymer 2 |
| 1.4 g | Polymer 3 |
| 0.16 g | Dye 1 |
| 3.2 g | Monomer 2 |
| 0.10 g | Phenylimino diacetic acid |
| 0.09 g | IR Dye I |
| 0.30 g | 2-(4-Methoxypheny1)-4,6-bis(trichloromethyl)-1,3,5-triazine |
| 0.30 g | 1H-1,2,4-triazole-5-thiol |

TABLE 3
Photosensitive composition for a negative working photopolymer
layer sensitized to 830 nm with coating weight of 1.4 g/m²

| | |
|---|---|
| 30 g | Propylene glycol monomethyl ether |
| 7 g | Methyl ethyl ketone |
| 0.09 g | IR Dye 2 |
| 2.28 g | Polymer 4 |
| 0.15 g | Bis(4-cumyl) iodonium tetraphenyl borate |
| 4.3 g | Monomer 3 |
| 0.2 g | Kayamer PM-2 |
| 1.8 g | Pigment 1 |
| 0.15 g | 1H-1,2,4-triazole-5-thiol |

TABLE 4
Photosensitive composition for a positive working plate
sensitized to 830 nm with coating weight of 1.5 g/m²

| | |
|---|---|
| 212 g | Propylene glycol monomethyl ether |
| 13 g | Methyl ethyl ketone |
| 16.5 g | Polymer 5 |
| 0.54 g | Crystal Violet |
| 0.54 g | S 0094 IR Dye available from FEW |
| | Chemicals (Germany) |
| 1.8 g | THPE |
| 0.5 g | Tego ® Glide 440 |

TABLE 5
Photosensitive composition for a negative working plate
sensitized to 830 nm with coating weight of 1.5 g/m²

| | |
|---|---|
| 6.8 g | Solution of a 25% resole GP649D99 |
| | from Georgia Pacific (Atlanta, GA, USA) |
| 8.4 g | Solution of 34% N-13 novolac from |
| | Eastman Kodak (Rochester, NY, USA) |
| 0.75 g | IR Dye 3 |
| 0.39 g | Terephthaldicarboxaldehyde |
| 0.02 g | Colorant dye D11 (PCAS, Longjumeau, France) |
| 0.2 g | Byk ® 307 |
| 80 g | Propylene glycol monomethyl ether |
| 3 g | Acetone |

### Developer D1

| | |
|---|---|
| 89 weight % | Water |
| 1 weight % | KOH solution (45 weight %) |
| 5 weightt % | Ethylan ™ SN 90 surfactant |
| 5 weight % | Triton ® H66 surfactant |

### Developer D2

| | |
|---|---|
| 82 weight % | Water |
| 1 weight % | Diethanolamine |
| 11 weight % | Octyl sulfone acid |
| 6 weight % | Phenoxyethanol |

### Developer D3

| | |
|---|---|
| 84 weight % | Water |
| 10 weight % | Sodium metasilicate |
| 1 weight % | Pluronic ® P 400 surfactant |
| 5 weight % | Triton ® H66 surfactant |

### Developer D4

| | |
|---|---|
| 85 weight % | Water |
| 10 weight % | Sodium metasilicate |
| 5 weight % | Glycol |

TABLE 6

| | Plate | | | Scratch | Number of plates |
|---|---|---|---|---|---|
| | Composition | Developer | Backside Coating | Sensitivity | cracked on press |
| Invention | TABLE 1 | D1 | Mowiol ® 4/88 poly(vinyl alcohol) obtained from | 4 | 0 |
| Example 1 | | | Kuraray (Germany) | | |
| Invention | TABLE 1 | D1 | Poly(ethylene oxide-co-propylene oxide) | 9 | 0 |
| Example 2 | | | | | |
| Invention | TABLE 1 | D1 | Poly(methyl methacrylate-co-acrylic acid) | 3 | 0 |
| Example 3 | | | | | |
| Invention | TABLE 1 | D1 | Lanco ™ Wax PE W 1555 wax emulsion obtained | 6 | 0 |
| Example 4 | | | from Langer Co. (Germany) | | |
| Invention | TABLE 1 | D1 | Emdex ® MTW/CC starch obtained from Emsland | 3 | 0 |
| Example 5 | | | Staerke (Germany) | | |
| Invention | TABLE 1 | D1 | Gum 850 obtained from Eastman Kodak Co. | 7 | 0 |
| Example 6 | | | | | |
| Invention | TABLE 2 | D2 | Poly(methyl methacrylate-co-acrylic acid) | 2 | 0 |
| Example 7 | | | | | |
| Invention | TABLE 2 | D2 | Mowiol ® 4/88 poly(vinyl alcohol) obtained from | 1 | 0 |
| Example 8 | | | Kuraray (Germany) | | |
| Invention | TABLE 2 | D2 | poly(ethylene oxide-co-propylene oxide) | 3 | 0 |
| Example 9 | | | | | |
| Invention | TABLE 2 | D2 | Lanco ™ Wax PE W 1555 wax emulsion obtained | 0 | 0 |
| Example 10 | | | from Langer Co. (Germany) | | |
| Invention | TABLE 2 | D2 | Emdex ™ MTW/CC starch obtained from Emsland | 2 | 0 |
| Example 11 | | | Staerke (Germany) | | |
| Invention | TABLE 2 | D2 | Gum 850 obtained from Eastman Kodak Co. | 4 | 0 |
| Example 12 | | | | | |
| Invention | TABLE 3 | D1 | Poly(methyl methacrylate-co-acrylic acid) | 5 | 0 |
| Example 13 | | | | | |
| Invention | TABLE 3 | D1 | Mowiol ® 4/88 poly(vinyl alcohol) obtained from | 2 | 0 |
| Example 14 | | | Kuraray (Germany) | | |
| Invention | TABLE 3 | D1 | Poly(ethylene oxide-co-propylene oxide) | 4 | 0 |
| Example 15 | | | | | |
| Invention | TABLE 3 | D1 | Lanco ™ Wax PE W 1555 wax emulsion obtained | 2 | 0 |
| Example 16 | | | from Langer Co. (Germany) | | |
| Invention | TABLE 3 | D1 | Emdex ™ MTW/CC starch obtained from Emsland | 3 | 0 |
| Example 17 | | | Staerke (Germany) | | |
| Invention | TABLE 3 | D1 | Gum 850 obtained from Eastman Kodak Co. | 4 | 0 |
| Example 18 | | | | | |
| Invention | TABLE 4 | D3 | Poly(ethylene oxide-co-propylene oxide) | 7 | 0 |
| Example 19 | | | | | |
| Invention | TABLE 4 | D3 | Poly(methyl methacrylate-co-acrylic acid) | 5 | 0 |
| Example 20 | | | | | |
| Invention | TABLE 4 | D3 | Lanco ™ Wax PE W 1555 wax emulsion obtained | 3 | 0 |
| Example 21 | | | from Langer Co. (Germany) | | |
| Invention | TABLE 4 | D3 | Emdex ™ MTW/CC starch obtained from Emsland | 4 | 0 |
| Example 22 | | | Staerke (Germany) | | |
| Invention | TABLE 4 | D3 | Gum 850 obtained from Eastman Kodak Co. | 6 | 0 |
| Example 23 | | | | | |
| Invention | TABLE 4 | D3 | Novolak | 4 | 0 |
| Example 24 | | | | | |
| Invention | TABLE 5 | D4 | Mowiol ® 4/88 poly(vinyl alcohol) obtained from | 4 | 0 |
| Example 25 | | | Kuraray (Germany) | | |
| Invention | TABLE 5 | D4 | Poly(ethylene oxide-co-propylene oxide) | 3 | 0 |
| Example 26 | | | | | |
| Invention | TABLE 5 | D4 | Poly(methyl methacrylate-co-acrylic acid | 4 | 0 |
| Example 27 | | | | | |
| Invention | TABLE 5 | D4 | Lanco ™ Wax PE W 1555 wax emulsion obtained | 6 | 0 |
| Example 28 | | | from Langer Co. (Germany) | | |
| Invention | TABLE 5 | D4 | Emdex ™ MTW/CC starch obtained from Emsland | 1 | 0 |
| Example 29 | | | Staerke (Germany) | | |
| Invention | TABLE 5 | D4 | Gum 850 obtained from Eastman Kodak Co. | 2 | 0 |
| Example 30 | | | | | |
| Invention | TABLE 5 | D4 | Novolak | 1 | 0 |
| Example 31 | | | | | |
| Comparative | TABLE 1 | D1 | None | 40 | 0 |
| Example 1 | | | | | |
| Comparative | TABLE 2 | D2 | None | 36 | 0 |
| Example 2 | | | | | |
| Comparative | TABLE 3 | D1 | None | 47 | 0 |
| Example 3 | | | | | |
| Comparative | TABLE 1 | D1 | None | 60 | 0 |
| Example 4 | | | | | |
| Comparative | TABLE 2 | D2 | None | 45 | 0 |
| Example 5 | | | | | |
| Comparative | TABLE 3 | D1 | None | 45 | 0 |
| Example 6 | | | | | |
| Comparative | TABLE 1 | D1 | 1 g/m² Epoxy resin 1 | 2 | 3 |
| Example 7 | | | | | |
| Comparative | TABLE 2 | D2 | 1 g/m² Epoxy resin 1 | 4 | 1 |
| Example 8 | | | | | |
| Comparative | TABLE 3 | D1 | 1 g/m² Epoxy resin 1 | 1 | 4 |
| Example 9 | | | | | |
| Comparative | TABLE 4 | D3 | 1 g/m² Epoxy resin 1 | 0 | 3 |
| Example 10 | | | | | |
| Comparative | TABLE 5 | D4 | 1 g/m² Epoxy resin 1 | 3 | 2 |
| Example 11 | | | | | |
| Comparative | TABLE 1 | D1 | 0.5 g/m² Crosslinked tetraethoxysilane as disclosed | 0 | 6 |
| Example 12 | | | in EP 1,566,283A2 (Example 5) | | |
| Comparative | TABLE 2 | D2 | 0.5 g/m² Crosslinked tetraethoxysilane as disclosed | 1 | 1 |
| Example 13 | | | in EP 1,566,283A2 (Example 5) | | |
| Comparative | TABLE 3 | D1 | 0.5 g/m² Crosslinked tetraethoxysilane as disclosed | 2 | 3 |
| Example 14 | | | in EP 1,566,283A2 (Example 5) | | |
| Comparative | TABLE 4 | D3 | 0.5 g/m² Crosslinked tetraethoxysilane as disclosed | 0 | 3 |
| Example 15 | | | in EP 1,566,283A2 (Example 5) | | |
| Comparative | TABLE 5 | D4 | 0.5 g/m² Crosslinked tetraethoxysilane as disclosed | 4 | 4 |
| Example 16 | | | in EP 1,566,283A2 (Example 5) | | |

The polymers used in Invention Examples 2, 3, 7, 9, 13, 15, 19, 20, 24, and 31 and Comparative Examples 1-6 are easily prepared or purchased polymers.

The invention has been described in detail with particular reference to certain preferred embodiments thereof, but it will be understood that variations and modifications can be effected within the spirit and scope of the invention.

1. A lithographic printing plate precursor comprising a substrate and having thereon a radiation-sensitive imageable layer on the front side the substrate,
the precursor being developable in a processing solution having a pH of at least 6.5 after imagewise irradiation using imaging radiation,
the precursor further comprising a non-radiation-sensitive layer on the back side of the substrate, whereby at least 80 weight % of the non-radiation-sensitive layer is removable when contacted by the processing solution for 5 to 50 seconds at 20° C. to 40° C.

2. The lithographic printing plate precursor of claim 1 wherein at least 80 weight % of the non-radiation-sensitive layer is removable in the processing solution that is an alkaline developer comprising a silicate or metasilicate and having a pH of at least 8, when the precursor is contacted by the processing solution for 10 to 30 seconds at 20° C. to 30° C.

3. The lithographic printing plate precursor of claim 1 wherein at least 80 weight % of the non-radiation-sensitive layer is removable in the processing solution that is free of silicates and metasilicates and has a pH of from 6.5 to 12.5, when the precursor is contacted by the processing solution for 10 to 30 seconds at 20° C. to 30° C.

4. The lithographic printing plate precursor of claim 1 wherein, upon removal of the non-radiation-sensitive layer, the backside surface of the substrate has a roughness Rₐ of at least 0.1 μm.

5. The lithographic printing plate precursor of claim 1 wherein the substrate comprises an anodized and grained aluminum support.

6. The lithographic printing plate precursor of claim 1 wherein the non-radiation-sensitive layer is composed of a non-crosslinked polymeric material in an amount of at least 80 weight % based on the total layer dry weight.

7. The lithographic printing plate precursor of claim 1 wherein the non-radiation-sensitive layer comprises one or more of the following materials in an amount of at least 80 weight % based on the total layer dry weight:
a poly(vinyl alcohol,
poly(vinyl pyrrolidone) or a copolymer derived in part from vinyl pyrrolidone,
a starch,
gum Arabic,
a polymer having pendant acidic groups, or salts thereof,
a poly(alkylene oxide),
a novolak or resole resin,
a poly(vinyl acetal) with acidic or phenolic groups,
a polyurethane with acidic side groups, and
hydrophilic wax dispersion.

8. The lithographic printing plate precursor of claim 1 wherein the non-radiation-sensitive layer comprises one or more non-removable components that are not removable in the processing solution under the noted conditions, and these non-removable components comprise less than 20 weight % of the total layer dry weight.

9. The lithographic printing plate precursor of claim 1 wherein the non-radiation-sensitive layer comprises discontinuous particulate materials dispersed within one or more binder materials.

10. The lithographic printing plate precursor of claim 1 wherein the non-radiation-sensitive layer is present at a dry coverage of 0.1 to 5 g/m².

11. The lithographic printing plate precursor of claim 1 wherein the non-radiation-sensitive layer is present at a dry coverage of from about 0.3 to about 2 g/m².

12. The lithographic printing plate precursor of claim 1 wherein the non-radiation-sensitive layer further includes one or more of a plasticizer, surfactant, matte agent, dye, or pigment.

13. The lithographic printing plate precursor of claim 1 wherein the radiation-sensitive imageable layer is sensitive to radiation in the range of 350 to 450 nm or in the range of from 750 to 1250 nm.

14. The lithographic printing plate precursor of claim 1 wherein the radiation-sensitive imageable layer is sensitive to infrared radiation and is positive-working

15. The lithographic printing plate precursor of claim 1 wherein the radiation-sensitive imageable layer is sensitive to infrared radiation and positive-working, and is disposed over an inner layer that is disposed on the substrate.

16. The lithographic printing plate precursor of claim 1 wherein the radiation-sensitive imageable layer is negative-working.

17. The lithographic printing plate precursor of claim 1 wherein the radiation-sensitive imageable layer comprises particles that are coalesceable upon exposure to imaging radiation.

18. A stack comprising two or more of the lithographic printing plate precursors of claim 1, wherein the non-radiation-sensitive layer of an uppermost precursor is in direct contact with the front side of the precursor below it, without interleaf paper between the adjacent precursors.

19. The stack of claim 18 comprising at least 20 of the lithographic printing plate precursors, wherein no interleaf paper is provided between any adjacent precursors.

20. A method of providing a lithographic printing plate comprising:
A) imagewise exposing the lithographic printing plate precursor of claim 1 to provide imagewise exposed and non-exposed regions in the radiation-sensitive imageable layer on the front side,
B) prior to or after step A, contacting the lithographic printing plate precursor with a processing solution having a pH of at least 6.5, for 5 to 50 seconds at 20° C. to 40° C., to remove at least 80 weight % of the non-radiation-sensitive layer on the back side of the substrate, and
C) after step A, but prior to, during, or after step B, processing the precursor to provide a lithographic image on its front side.

21. The method of claim 20 wherein the imagewise exposing is carried out using radiation the range of from 350 to 450 nm, or in the range of from 750 to 1250 nm.

22. The method of claim 20 wherein step B is carried simultaneously with step C, off-press, and the processing solution is an alkaline developer containing a silicate or a metasilicate.

23. The method of claim 20 wherein step B is carried out after step A but before step C and the processing solution is an aqueous rinse solution that is free of silicates and metasilicates.

24. The method of claim 20 wherein step B is carried out after steps A and C and the processing solution is an aqueous post-rinse solution that is free of silicates and metasilicates.

25. The method of claim 20 wherein step B removes at least 80 weight % of the non-radiation-sensitive layer and the substrate is an aluminum-containing substrate having a back side roughness Rₐ of at least 0.1 μm where the non-radiation-sensitive layer is removed.

26. The method of claim 20 wherein step B removes at least 80 weight %, but less than 95 weight %, of the non-radiation-sensitive layer, leaving non-removable components that are adhered to the back side of the substrate that is an anodized and grained aluminum substrate after steps B and C.

27. The method of claim 20 wherein the lithographic image is used for lithographic printing.

28. The method of claim 20 wherein the non-radiation-sensitive layer comprises one or more of the following materials in an amount of at least 80 weight % based on the total layer dry weight:
a poly(vinyl alcohol,
poly(vinyl pyrrolidone) or a copolymer derived in part from vinyl pyrrolidone,
a starch,
gum Arabic,
a polymer having pendant acidic groups, or salts thereof,
a poly(alkylene oxide),
a novolak or resole resin,
a poly(vinyl acetal) with acidic or phenolic groups,
a polyurethane with acidic side groups, and
hydrophilic wax dispersion.
